(19) United States
(12) Patent Application Publication
(10) Pub. No.: US 2026/0040860 A1
(43) Pub. Date: Feb. 5, 2026

(54) SUBSTRATE PROCESSING METHOD AND SUBSTRATE PROCESSING SYSTEM

(71) Applicant: Tokyo Electron Limited, Tokyo (JP)

(72) Inventors: Tatsuya NAGAMATSU, Kumamoto (JP); Daiki MORIMOTO, Kumamoto (JP)

(21) Appl. No.: 19/283,060

(22) Filed: Jul. 28, 2025

(30) Foreign Application Priority Data
Jul. 31, 2024 (JP) 2024-124605

(51) Int. Cl. H01L 21/67; H01L 21/677; H01L 21/68

(52) U.S. Cl. CPC H01L 21/67034; H01L 21/67288; H01L 21/67748; H01L 21/67781; H01L 21/681

(57) ABSTRACT

A substrate processing method according to an aspect of the present disclosure includes performing a batch processing to process a plurality of substrates at once, performing a single-substrate processing to process the plurality of substrate one by one after the batch processing, identifying a position of a cutout provided on an outer periphery of a substrate subjected to the batch processing, and rotating the substrate such that the identified position of the cutout reaches a first position. The performing the single-substrate processing includes drying the substrate, and the rotating the substrate is performed before the drying the substrate.

### CROSS-REFERENCE TO RELATED APPLICATIONS

This application is based on and claims priority from Japanese Patent Application No. 2024-124605, filed on Jul. 31, 2024, with the Japan Patent Office, the disclosure of which is incorporated herein in its entirety by reference.

### TECHNICAL FIELD

The present disclosure relates to a substrate processing method and a substrate processing system.

### BACKGROUND

A substrate processing system has been known, which includes a batch processing section, a single-substrate processing section, and an interface section. The batch processing section processes a lot containing a plurality of substrates at once. The single-substrate processing section processes the substrates in the lot one by one. The interface section delivers the substrates from the batch processing section to the single-substrate processing section. See, for example, Japanese Patent Laid-open Publication Nos. 2023-129235, 2023-121707, and 2023-121571.

### SUMMARY

A substrate processing method according to an aspect of the present disclosure includes performing a batch processing to process a plurality of substrates at once, performing a single-substrate processing to process the plurality of substrate one by one after the batch processing, identifying a position of a cutout provided on an outer periphery of a substrate subjected to the batch processing, and rotating the substrate such that the identified position of the cutout reaches a first position. The performing the single-substrate processing includes drying the substrate. The rotating the substrate is performed before the drying the substrate.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic plan view illustrating a substrate processing system according to an embodiment.

FIG. 2 is a plan view illustrating an example of a substrate.

FIGS. 3A and 3B are views illustrating an example of a second delivery table of FIG. 1.

FIG. 4 is a view illustrating an example of a liquid processing device of FIG. 1.

FIG. 5 is a view illustrating an example of a drying device of FIG. 1.

FIG. 6 is a flowchart illustrating a substrate processing method according to an embodiment.

FIG. 7 is a view illustrating an example of a notch position before chemical liquid processing.

FIG. 8 is a view illustrating an example of a notch position after chemical liquid processing.

FIG. 9 is a flowchart illustrating an example of notch position adjustment control.

FIG. 10 is a diagram illustrating an example of notch position adjustment control.

FIG. 11 is a view illustrating a first modification of the second delivery table of FIG. 1.

FIG. 12 is a view illustrating a second modification of the second delivery table of FIG. 1.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, non-limiting embodiments of the present disclosure will be described with reference to the accompanying drawings. In all the accompanying drawings, the same or corresponding members or components will be denoted by the same or corresponding reference numerals, and redundant descriptions thereof will be omitted.

In the following description, an XYZ orthogonal coordinate system is used, but this coordinate system is defined solely for explanatory purposes and does not limit the posture of a substrate processing system 1. A view from the XY plane may be referred to as “a plan view,” and from an arbitrary viewpoint, the positive Z-axis direction may be referred to as “upward,” and the negative Z-axis direction may be referred to as “downward.”

### [Substrate Processing System]

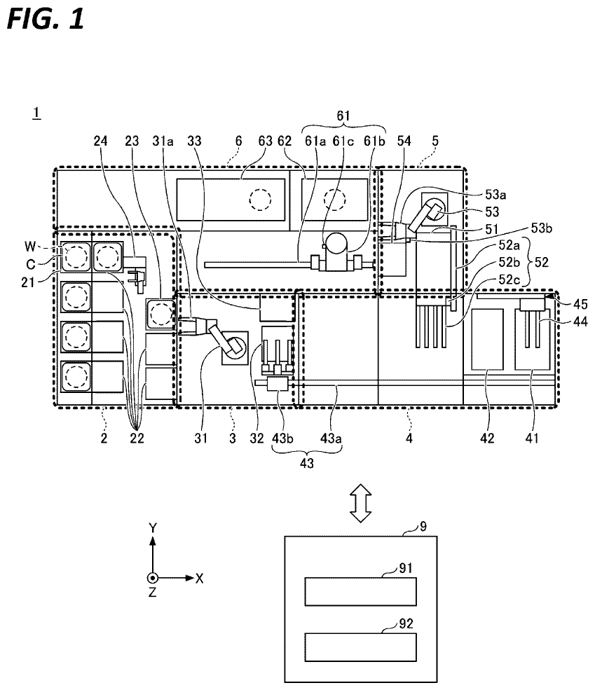

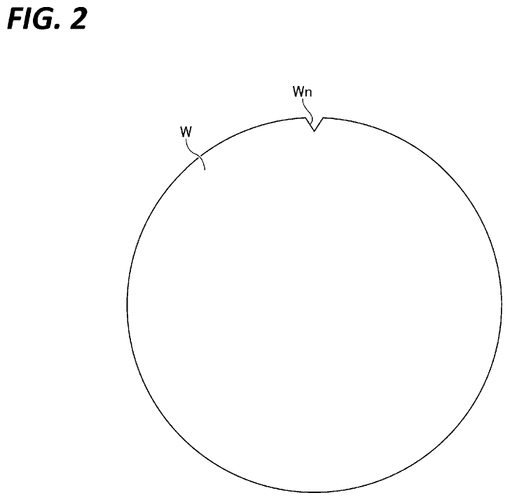

The substrate processing system 1 according to an embodiment will be described with reference to FIGS. 1 and 2. FIG. 1 is a plan view illustrating the substrate processing system 1 according to the embodiment. FIG. 2 is a plan view illustrating an example of a substrate W.

As illustrated in FIG. 1, the substrate processing system 1 includes a loading/unloading section 2, a first interface section 3, a batch processing section 4, a second interface section 5, a single-substrate processing section 6, and a control circuit 9.

The loading/unloading section 2 serves as both a loading section and an unloading section. This configuration allows the substrate processing system 1 to be compact. The loading/unloading section 2 includes a load port 21, a stocker 22, a loader 23, and a cassette transfer device 24.

The load port 21 is arranged on the negative X-axis side of the loading/unloading section 2. A plurality of (e.g., four) load ports 21 are arranged along the Y-axis. The number of load ports 21 is not particularly limited. A cassette C is placed on each load port 21. The cassette C accommodates a plurality of (e.g., 25) substrates W. The substrate W has a notch Wn, as illustrated in FIG. 2. The notch Wn is provided on the outer periphery of the substrate W. The notch Wn is an example of a cutout. The cassette C is loaded into and unloaded from the load port 21. The substrates W are horizontally held at a second pitch P2, which is N times a first pitch P1 along the Z-axis (P2=N×P1), in the inside of the cassette C. N is a natural number of 2 or more. In the present embodiment, N is 2, but N may also be 3 or more.

A plurality of (e.g., four) stockers 22 arranged along the Y-axis are located on the X-axis center of the loading/unloading section 2. A plurality of (e.g., two) stockers 22 arranged along the Y-axis are located adjacent to the first interface section 3 on the positive X-axis side of the loading/unloading section 2. The stockers 22 may also be arranged in multiple stages along the Z-axis. The stockers 22 temporarily store, for example, cassettes C in which substrates W before cleaning are accommodated, or cassettes C that are empty after the substrates W have been removed. The number of stockers 22 is not particularly limited.

The loader 23 is located adjacent to the first interface section 3. The loader 23 is located on the positive X-axis side of the loading/unloading section 2. The cassette C is placed on the loader 23. The loader 23 is provided with a lid opening/closing mechanism (not illustrated) for opening and closing a lid of the cassette C. A plurality of loaders 23 may be provided. The loaders 23 may also be arranged in multiple stages along the Z-axis.

The cassette transfer device 24 transfers the cassette C between the load port 21, the stocker 22, and the loader 23. The cassette transfer device 24 may be, for example, a multi-joint transfer robot.

The first interface section 3 is located on the positive X-axis side of the loading/unloading section 2. The first interface section 3 transfers the substrate W between the load/unloading section 2, the batch processing section 4, and the single-substrate processing section 6. The first interface section 3 includes a substrate transfer device 31, a lot forming unit 32, and a first delivery table 33.

The substrate transfer device 31 transfers the substrate W between the cassette C placed on the loader 23, the lot forming unit 32, and the first delivery table 33. The substrate transfer device 31 is configured as a multi-axis (e.g., 6-axis) arm robot and has a substrate holding arm 31a at the tip thereof. The substrate holding arm 31a has a plurality of holding claws (not illustrated) capable of holding a plurality of (e.g., 25) substrates W. The substrate holding arm 31a may move to an arbitrary position and take an arbitrary posture inside a three-dimensional space while holding the substrates W with the holding claws.

The lot forming unit 32 is located on the positive X-axis side of the first interface section 3. The lot forming unit 32 holds a plurality of substrates W at the first pitch P1 to form a lot.

The first delivery table 33 is located adjacent to the single-substrate processing section 6. The first delivery table 33 is located on the positive Y-axis side of the first interface section 3. The first delivery table 33 temporarily stores the substrate W received from the single-substrate processing section 6 until the substrate is delivered to the loading/unloading section 2.

The batch processing section 4 is located on the positive X-axis side of the first interface section 3. The loading/unloading section 2, the first interface section 3, and the batch processing section 4 are arranged in this order from the negative X-axis side toward the positive X-axis side. The batch processing section 4 processes a lot containing a plurality of (e.g., 50 or 100) substrates W at the first pitch P1 at once. One lot is constituted, for example, by the substrates W of M cassettes C. M is a natural number of 2 or more. M may be the same natural number as N or a different natural number from N. The batch processing section 4 includes a chemical liquid tank 41, a rinse liquid tank 42, a first transfer device 43, a processing tool 44, and a drive device 45.

The chemical liquid tank 41 and the rinse liquid tank 42 are arranged along the X-axis. For example, the chemical liquid tank 41 and the rinse liquid tank 42 are arranged in this order from the positive X-axis side toward the negative X-axis side. The chemical liquid tank 41 and the rinse liquid tank 42 are also collectively referred to as “processing tank”. The numbers of chemical liquid and rinse liquid tanks 41 and 42 are not limited to those in FIG. 1. For example, there is one set of the chemical liquid tank 41 and the rinse liquid tank 42 in FIG. 1, but there may be multiple sets.

The chemical liquid tank 41 stores a chemical liquid in which the lot is immersed. The chemical liquid is, for example, a phosphoric acid aqueous solution (H₃PO₄). The phosphoric acid aqueous solution selectively etches and removes a silicon nitride film among silicon oxide films and silicon nitride films. The chemical liquid is not limited to the phosphoric acid aqueous solution. The chemical liquid may be diluted hydrofluoric acid (DHF), a mixed liquid of hydrofluoric acid and ammonium fluoride (BHF), diluted sulfuric acid, a mixed liquid of sulfuric acid, hydrogen peroxide, and water (SPM), a mixed liquid of ammonia, hydrogen peroxide, and water (SC1), a mixed liquid of hydrochloric acid, hydrogen peroxide, and water (SC2), a mixed liquid of tetramethylammonium hydroxide and water (TMAH), a plating solution, and others. The chemical liquid may also be for peeling or plating. The number of types of chemical liquids is not particularly limited and may be two or more.

The rinse liquid tank 42 stores a first rinse liquid in which the lot is immersed. The first rinse liquid is pure water for removing the chemical liquid from the substrate W, and is, for example, deionized water (DIW).

The first transfer device 43 includes a guide rail 43a and a first transfer arm 43b. The guide rail 43a is located on the negative Y-axis side of the processing tank. The guide rail 43a extends along the X-axis from the first interface section 3 to the batch processing section 4. The first transfer arm 43b moves along the guide rail 43a. The first transfer arm 43b may also move along the Z-axis and may rotate around the Z-axis. The first transfer arm 43b collectively transfers the lot between the first interface section 3 and the batch processing section 4.

The processing tool 44 receives and holds the lot from the first transfer arm 43b. The processing tool 44 holds a plurality of substrates W at the first pitch P1 along the Y-axis and holds each of the plurality of substrates W vertically.

The drive device 45 moves the processing tool 44 along the X-axis and the Z-axis. The processing tool 44 immerses the lot in the chemical liquid stored in the chemical liquid tank 41, then immerses the lot in the first rinse liquid stored in the rinse liquid tank 42, and thereafter delivers the lot to the first transfer device 43.

The number of units of the processing tool 44 and the drive device 45 is one in the present embodiment, but may be plural. In the latter case, one unit immerses the lot in the chemical liquid stored in the chemical liquid tank 41, and another unit immerses the lot in the first rinse liquid stored in the rinse liquid tank 42. In this case, the drive device 45 may move the processing tool 44 along the Z-axis, and may not move the processing tool 44 along the X-axis.

The second interface section 5 is located on the positive Y-axis side of the batch processing section 4. The second interface section 5 transfers the substrate W between the batch processing section 4 and the single-substrate processing section 6. The second interface section 5 includes an immersion tank 51, a second transfer device 52, a third transfer device 53, and a second delivery table 54.

The immersion tank 51 is located outside the movement range of the first transfer arm 43b. For example, the immersion tank 51 is located at a position shifted to the positive Y-axis side relative to the processing tank. The immersion tank 51 stores a second rinse liquid in which the lot is immersed. The second rinse liquid is, for example, deionized water (DIW). The substrate W is held in the second rinse liquid until being lifted out from the second rinse liquid by the third transfer device 53. Since the substrate W exists below the liquid surface of the second rinse liquid, the surface tension of the second rinse liquid does not act on the substrate W, which may prevent the collapse of uneven patterns on the substrate W.

The second transfer device 52 includes a Y-axis drive device 52a, a Z-axis drive device 52b, and a second transfer arm 52c.

The Y-axis drive device 52a is located on the positive X-axis side of the second interface section 5. The Y-axis drive device 52a extends along the Y-axis from the second interface section 5 to the batch processing section 4. The Y-axis drive device 52a moves the Z-axis drive device 52b and the second transfer arm 52c along the Y-axis. The Y-axis drive device 52a may include a ball screw.

The Z-axis drive device 52b is movably attached to the Y-axis drive device 52a. The Z-axis drive device 52b moves the second transfer arm 52c along the Z-axis. The Z-axis drive device 52b may include a ball screw.

The second transfer arm 52c is movably attached to the Z-axis drive device 52b. The second transfer arm 52c receives and holds the lot from the first transfer arm 43b. The second transfer arm 52c holds a plurality of substrates W at the first pitch P1 along the Y-axis and holds each of the plurality of substrates W vertically. The second transfer arm 52c is moved along the Y-axis and the Z-axis by the Y-axis drive device 52a and the Z-axis drive device 52b. The second transfer arm 52c is configured to be movable between a plurality of positions including a delivery position, an immersion position, and a standby position.

The delivery position is a position where the lot is delivered between the first transfer arm 43b and the second transfer arm 52c. The delivery position is on the negative Y-axis side and the positive Z-axis side.

The immersion position is a position where the lot is immersed in the immersion tank 51. The immersion position is on the positive Y-axis side and the negative Z-axis side relative to the delivery position.

The standby position is a position where the second transfer arm 52c stands by when neither delivering the lot nor immersing the lot in the immersion tank 51. The standby position is immediately below the delivery position (on the negative Z-axis side), and is a position where the second transfer arm does not interfere with the movement of the first transfer arm 43b. In this case, the second transfer arm 52c may move to the delivery position only through upward movement (toward the positive Z-axis side), resulting in improved throughput. The standby position may also be the same as the immersion position. In this case, particles that may be generated during operation of the first transfer device 43 may be prevented from adhering to the second transfer arm 52c. The standby position may also be directly above (on the positive Z-axis side of) the immersion position. In this way, contact between the first transfer arm 43b and the second transfer arm 52c may be prevented by setting the standby position to be different from the delivery position.

The second transfer device 52 moves the second transfer arm 52c to the immersion position or the standby position while the first transfer device 43 is in operation. This may prevent contact between the first transfer arm 43b and the second transfer arm 52c.

The third transfer device 53 is configured as a multi-axis (e.g., 6-axis) arm robot and has a third transfer arm 53a at the tip thereof. The third transfer arm 53a has a holding claw (not illustrated) capable of holding a single substrate W. The third transfer arm 53a may move to an arbitrary position and take an arbitrary posture in a three-dimensional space while holding the substrate W with the holding claw. The third transfer device 53 transfers the substrate W between the second transfer arm 52c at the immersion position and the second delivery table 54. At this time, since the immersion tank 51 is located outside the movement range of the first transfer arm 43b, the first transfer arm 43b and the third transfer arm 53a do not interfere each other. This allows either the first transfer device 43 or the third transfer device 53 to be operated independently of the operation state of the other. Therefore, the first transfer device 43 and the third transfer device 53 may be operated at arbitrary timings, thereby shortening the time required for transferring the substrate W. As a result, the productivity of the substrate processing system 1 is improved.

The third transfer device 53 may include an imaging unit 53b. The imaging unit 53b is attached, for example, to the third transfer arm 53a. The imaging unit 53b captures an image of the upper surface of the substrate W transferred by the third transfer arm 53a to acquire an upper surface image of the substrate W. The imaging unit 53b transmits the acquired upper surface image to the control circuit 9. The control circuit 9 identifies the position of the notch Wn of the substrate W based on the upper surface image acquired by the imaging unit 53b. The imaging unit 53b may include a camera to generate an image using the camera. The imaging unit 53b may also include a laser light source and a camera, and may generate an image by an optical cutting method. The imaging unit 53b only needs to be capable of capturing the upper surface image of the substrate W transferred by the third transfer arm 53a, and may instead be attached, for example, to the sidewall or ceiling of the second interface section 5. In the example of FIG. 1, a single imaging unit 53b is provided, but two or more imaging units 53b may be provided. The imaging unit 53b is an example of an identifier.

The second delivery table 54 is located adjacent to the single-substrate processing section 6. The second delivery table 54 is located on the negative X-axis side of the second interface section 5. The second delivery table 54 temporarily stores the substrate W received from the third transfer device 53 until the substrate is delivered to the single-substrate processing section 6. The substrate W taken out from the immersion tank 51 is placed on the second delivery table 54. The substrate W placed on the second delivery table 54 is, for example, in a state where the surface thereof is wet with the second rinse liquid. In this case, the surface tension of the second rinse liquid does not act on the substrate W, which may prevent the collapse of uneven patterns on the substrate W. The number of second delivery tables 54 may be one, or two or more.

The single-substrate processing section 6 is located on the negative X-axis side of the second interface section 5. The single-substrate processing section 6 is located on the positive Y-axis side of the loading/unloading section 2, the first interface section 3, and the batch processing section 4. The single-substrate processing section 6 processes the substrate W one by one. The single-substrate processing section 6 includes a fourth transfer device 61, a liquid processing device 62, and a drying device 63.

The fourth transfer device 61 includes a guide rail 61a and a fourth transfer arm 61b. The fourth transfer device 61 may include an imaging unit 61c.

The guide rail 61a is located on the negative Y-axis side of the single-substrate processing section 6. The guide rail 61a extends along the X-axis in the single-substrate processing section 6.

The fourth transfer arm 61b moves along the guide rail 61a. The fourth transfer arm 61b rotates around the Z-axis. The fourth transfer arm 61 transfers the substrate W between the second delivery table 54, the liquid processing device 62, the drying device 63, and the first delivery table 33. The number of fourth transfer arms 61b may be one, or two or more, and in the latter case, the fourth transfer device 61 collectively transfers a plurality of (e.g., five) substrates W.

The imaging unit 61c is attached to the fourth transfer arm 61b. The imaging unit 61c captures an image of the upper surface of the substrate W transferred by the fourth transfer arm 61b to acquire an upper surface image of the substrate W. The imaging unit 61c transmits the acquired upper surface image to the control circuit 9. The control circuit 9 identifies the position of the notch Wn of the substrate W based on the upper surface image acquired by the imaging unit 61c. The imaging unit 61c may have the same configuration as the imaging unit 53b. The second imaging unit 61c only needs to be capable of capturing the upper surface image of the substrate W transferred by the fourth transfer arm 61b, and may instead be attached, for example, to the sidewall or ceiling of the single-substrate processing section 6. In the example of FIG. 1, a single imaging unit 61c is provided, but two or more imaging units 61c may be provided. The imaging unit 61c is an example of an identifier.

The liquid processing device 62 is located on the positive X-axis side and the positive Y-axis side of the single-substrate processing section 6. The liquid processing device 62 is of a single-substrate type and processes the substrates W with a processing liquid one by one. The liquid processing device 62 is arranged in multiple stages (e.g., three stages) along the Z-axis. This allows a plurality of substrates W to be simultaneously processed with the processing liquid. There may be multiple types of processing liquids such as pure water (e.g., DIW) and a drying liquid having a lower surface tension than pure water. The drying liquid may be an alcohol such as isopropyl alcohol (IPA).

The drying device 63 is located adjacent to the negative X-axis side relative to the liquid processing device 62. In this case, the end surface on the positive Y-axis side of the single-substrate processing section 6 may be aligned with or approximately aligned with the end surface on the positive Y-axis side of the second interface section 5. Therefore, almost no dead space is generated, so that the footprint of the substrate processing system 1 may be reduced. In contrast, when the drying device 63 is located adjacent to the positive Y-axis side relative to the liquid processing device 62, the end surface on the positive Y-axis side of the single-substrate processing section 6 would protrude beyond the end surface on the positive Y-axis side of the second interface section 5, which may result in a dead space. The drying device 63 is of a single-substrate type and dries the substrates W with a supercritical fluid one by one. The drying device 63 is arranged in multiple stages (e.g., three stages) along the Z-axis. This allows a plurality of substrates W to be dried simultaneously.

It is not necessary for both the liquid processing device 62 and the drying device 63 to be of a single-substrate type. For example, the liquid processing device 62 may be of a single-substrate type, while the drying device 63 may be of a batch type. The drying device 63 may dry a plurality of substrates W at once with a supercritical fluid. The number of substrates W processed at once in the drying device 63 may be equal to or greater than the number of substrates W processed at once in the liquid processing device 62, but may also be less. Devices other than the liquid processing device 62 and the drying device 63 may also be arranged in the single-substrate processing section 6.

The control circuit 9 is, for example, a computer. The control circuit 9 includes a processor 91 such as a central processing unit (CPU) and a storage 92 such as a memory. The storage 92 stores programs that control various types of processing executed in the substrate processing system 1. The control circuit 9 causes the processor 91 to execute the programs stored in the storage 92, thereby controlling the operation of the substrate processing system 1.

The control circuit 9 includes an electronic circuit such as a CPU, Field Programmable Gate Array (FPGA) or Application Specific Integrated Circuit (ASIC), and executes various control operations described in this specification by executing instruction codes stored in a memory or by being specifically designed for particular applications.

In the substrate processing system 1, the substrate W is transferred from the loading/unloading section 2 to the first interface section 3, the batch processing section 4, the second interface section 5, and the single-substrate processing section 6 in this order, and is then returned to the loading/unloading section 2.

### [Second Delivery Table]

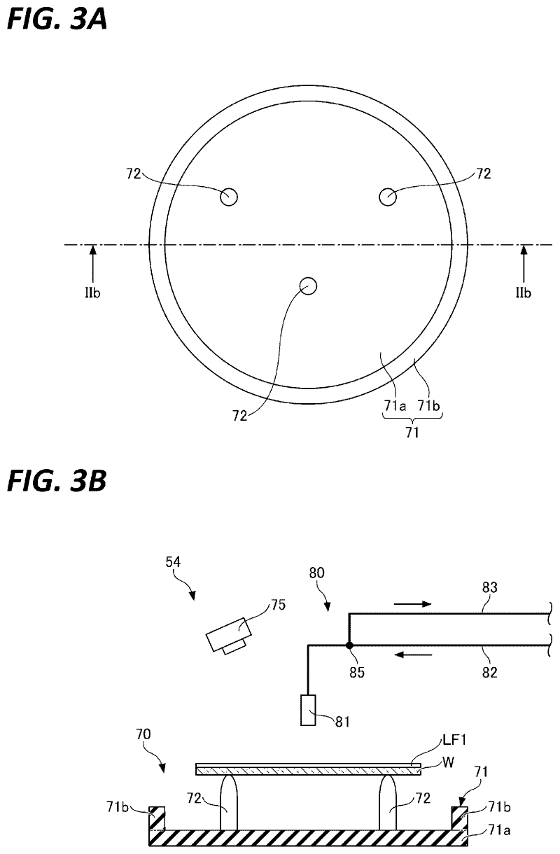

An example of the second delivery table 54 will be described with reference to FIGS. 3A and 3B. FIGS. 3A and 3B are views illustrating an example of the second delivery table 54 of FIG. 1. FIG. 3A is a plan view. FIG. 3B is a cross-sectional view taken along line IIb-IIb in FIG. 3A.

As illustrated in FIGS. 3A and 3B, the second delivery table 54 includes a substrate holding unit 70, an imaging unit 75, and a pure water supply unit 80. In FIG. 3A, the pure water supply unit 80 is omitted.

The substrate holding unit 70 includes a liquid receiver 71 and a plurality of pins 72. The liquid receiver 71 includes a bottom plate 71a and a wall portion 71b. The bottom plate 71a has a disc shape. The wall portion 71b is annularly provided on the bottom plate 71a. The plurality of pins 72 are provided on the bottom plate 71a. In the example of FIG. 3, the number of pins 72 is three, but may be four or more. The plane including the top of each pin 72 is horizontal. The top of each pin 72 is positioned higher than the top of the wall portion 71b. The plurality of pins 72 hold, from below, the substrate W above the bottom plate 71a. A first liquid film LF1, which is a liquid film of the second rinse liquid, may be formed on the upper surface of the substrate W.

The imaging unit 75 is provided above the substrate holding unit 70. The imaging unit 75 captures an image of the upper surface of the substrate W held by the pins 72 to acquire the upper surface image of the substrate W. For example, the imaging unit 75 captures the upper surface image of the substrate W held by the pins 72 before the pure water supply unit 80 supplies pure water to the substrate W. The imaging unit 75 may alternatively capture the upper surface image of the substrate W held by the pins 72 after the pure water supply unit 80 supplies pure water to the substrate W. The imaging unit 75 transmits the acquired upper surface image to the control circuit 9. The control circuit 9 identifies the position of the notch Wn of the substrate W based on the upper surface image acquired by the imaging unit 75. The imaging unit 75 may have the same configuration as the imaging unit 53b. The imaging unit 75 only needs to be capable of capturing the upper surface image of the substrate W held by the pins 72. In the example of FIG. 3, a single imaging unit 75 is provided, but two or more imaging units 75 may be provided. The imaging unit 75 is an example of an identifier.

The pure water supply unit 80 supplies pure water to the upper surface of the substrate W. The pure water supply unit 80 includes a nozzle 81, a pure water supply line 82, and a return line 83. The pure water supply line 82 is connected to the nozzle 81. The nozzle 81 discharges pure water supplied through the pure water supply line 82. A branch point 85 is provided in the pure water supply line 82, and the return line 83 is connected to the branch point 85. Even during a period when pure water is not being discharged from the nozzle 81, pure water flows through a portion of the pure water supply line 82 upstream of the branch point 85 and through the return line 83.

### [Liquid Processing Device]

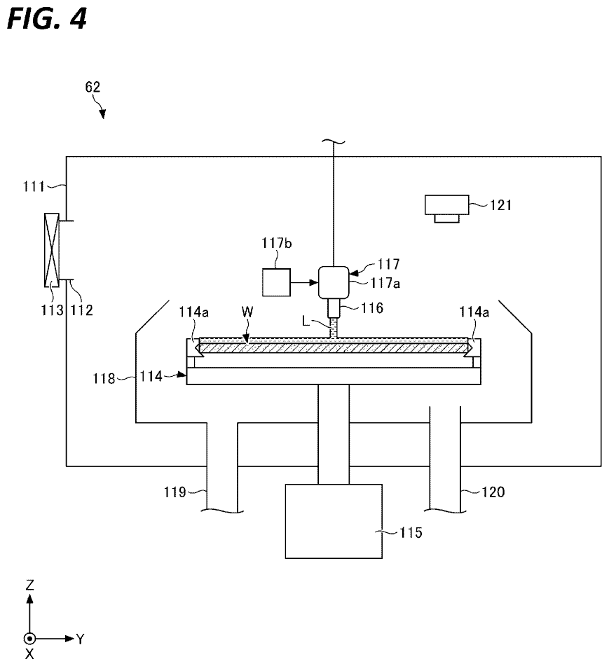

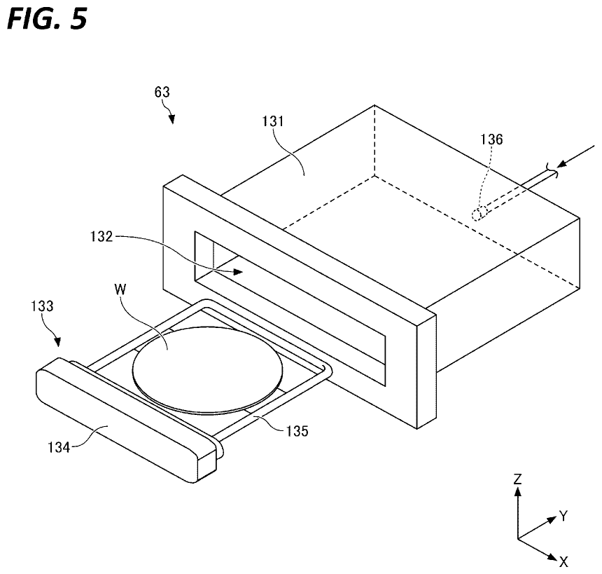

An example of the liquid processing device 62 will be described with reference to FIG. 4. FIG. 4 is a view illustrating an example of the liquid processing device 62 of FIG. 1.

As illustrated in FIG. 4, the liquid processing device 62 includes a processing container 111, a substrate holding unit 114, a substrate rotating unit 115, a nozzle 116, a nozzle moving unit 117, a cup 118, a drain pipe 119, and an exhaust pipe 120. The liquid processing device 62 may also include an imaging unit 121.

The processing container 111 accommodates components such as the substrate holding unit 114. A gate 112 and a gate valve 113 are provided on the sidewall of the processing container 111. The gate valve 113 opens and closes the gate 112. The substrate W is loaded to the inside of the processing container 111 through the gate 112 by the fourth transfer device 61 (see, e.g., FIG. 1). The substrate W is processed with a processing liquid L in the inside of the processing container 111. The substrate W is unloaded out of the processing container 111 through the gate 112 by the fourth transfer device 61.

The substrate holding unit 114 is provided in the inside of the processing container 111. The substrate holding unit 114 holds the substrate W horizontally. The substrate holding unit 114 includes a plurality of (e.g., three) clamps 114a. The plurality of clamps 114a are provided at equal intervals in the circumferential direction of the substrate W. Each clamp 114a holds the outer periphery of the substrate W.

The substrate rotating unit 115 rotates the substrate holding unit 114, thereby rotating the substrate W together with the substrate holding unit 114. The substrate rotating unit 115 includes, for example, a motor.

The nozzle 116 supplies the processing liquid L to the substrate W. For example, the nozzle 116 supplies the processing liquid L to the rotating substrate W.

The nozzle moving unit 117 moves the nozzle 116 in the horizontal direction. The nozzle moving unit 117 moves, for example, the nozzle 116 in the radial direction of the substrate W. The nozzle moving unit 117 includes an arm 117a and a drive 117b. The arm 117a holds the nozzle 116. The drive 117b pivots the arm 117a.

The cup 118 surrounds the outer periphery of the substrate W held by the substrate holding unit 114. The cup 118 collects the processing liquid L scattered from the outer periphery of the substrate W.

The drain pipe 119 and the exhaust pipe 120 are provided at the bottom of the cup 118. The drain pipe 119 discharges the processing liquid L accumulated in the inside of the cup 118. The exhaust pipe 120 discharges a gas accumulated in the inside of the cup 118.

The imaging unit 121 is provided above the substrate holding unit 114. The imaging unit 121 captures an image of the upper surface of the substrate W held by the substrate holding unit 114 to acquire the upper surface image of the substrate W. For example, the imaging unit 121 captures the upper surface image of the substrate W held by the substrate holding unit 114 before the nozzle 116 supplies the processing liquid L to the substrate W. The imaging unit 121 may alternatively capture the upper surface image of the substrate W held by the substrate holding unit 114 after the nozzle 116 supplies the processing liquid L to the substrate W. The imaging unit 121 transmits the acquired upper surface image to the control circuit 9. The control circuit 9 identifies the position of the notch Wn of the substrate W based on the upper surface image acquired by the imaging unit 121. The imaging unit 121 may have the same configuration as the imaging unit 53b. The imaging unit 121 only needs to be capable of capturing the upper surface image of the substrate W held by the substrate holding unit 114. In the example of FIG. 4, a single imaging unit 121 is provided, but two or more imaging units 121 may be provided. The imaging unit 121 is an example of an identifier.

### [Drying Device]

An example of the drying device 63 will be described with reference to FIG. 5. FIG. 5 is a view illustrating an example of the drying device 63 of FIG. 1.

As illustrated in FIG. 5, the drying device 63 includes a pressure-resistant container 131, a movable tray 133, and a supply port 136. The pressure-resistant container 131 has a loading/unloading port 132 for loading and unloading the substrate W. The movable tray 133 includes a lid 134 and a holding unit 135. The lid 134 opens and closes the loading/unloading port 132. The holding unit 135 holds the substrate W horizontally. With the lid 134 closing the loading/unloading port 132, the holding unit 135 holds the substrate W horizontally in the inside of the pressure-resistant container 131. The supply port 136 supplies a supercritical fluid such as carbon dioxide to the inside of the pressure-resistant container 131. The number and position of supply ports 136 are not limited to those illustrated in FIG. 5.

### [Operation of Substrate Processing System]

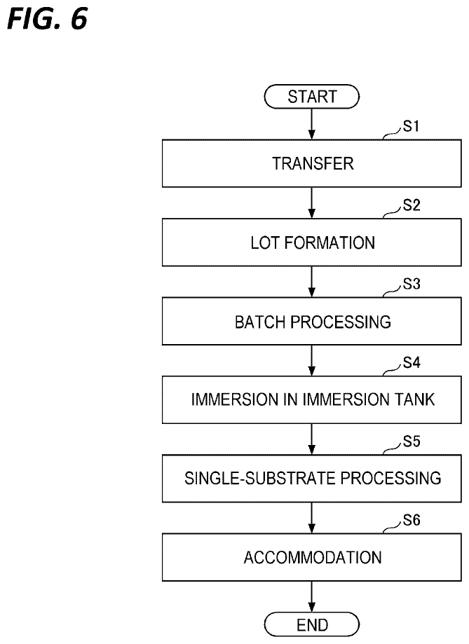

The operation of the substrate processing system 1 according to the embodiment, i.e., a substrate processing method will be described with reference to FIGS. 1 and 6. FIG. 6 is a flowchart illustrating a substrate processing method according to an embodiment. The substrate processing method illustrated in FIG. 6 is performed under the control of the control circuit 9.

First, the cassette C accommodating a plurality of substrates W is loaded into the loading/unloading section 2 and is placed on the load port 21. The substrates W are horizontally held at the second pitch P2 (P2=N×P1) along the Z-axis in the inside of the cassette C. N is a natural number of 2 or more. In the present embodiment, N is 2, but N may also be 3 or more.

Next, the cassette transfer device 24 transfers the cassette C from the load port 21 to the loader 23. The cassette C transferred to the loader 23 has a lid opened by a lid opening/closing mechanism.

Next, the substrate transfer device 31 receives the substrates W accommodated in the cassette C (step S1 in FIG. 6) and transfers the substrates W to the lot forming unit 32.

Next, the lot forming unit 32 holds a plurality of substrates W at the first pitch P1 (P1=P2/N) to form a lot (step S2 in FIG. 6). One lot is constituted, for example, by the substrates W of M cassettes C. Since the pitch of the substrates W is reduced from the second pitch P2 to the first pitch P1, the number of substrates W that are processed at once may be increased.

Next, the first transfer device 43 receives the lot from the lot forming unit 32 and transfers the lot to the processing tool 44.

Next, the processing tool 44 descends from above the chemical liquid tank 41 to immerse the lot in the chemical liquid, and performs chemical liquid processing (step S3 in FIG. 6). After that, the processing tool 44 ascends to lift the lot from the chemical liquid and then moves to the negative X-axis side above the rinse liquid tank 42.

Next, the processing tool 44 descends from above the rinse liquid tank 42 to immerse the lot in the first rinse liquid, and performs rinse liquid processing (step S3 in FIG. 6). After that, the processing tool 44 ascends to lift the lot from the first rinse liquid. Subsequently, the first transfer device 43 receives the lot from the processing tool 44 and delivers the lot to the second transfer device 52.

Next, the second transfer arm 52c of the second transfer device 52 moves to the positive Y-axis side, and descends from above the immersion tank 51 to immerse the lot in the second rinse liquid (step S4 in FIG. 6). The plurality of substrates W in the lot are held in the second rinse liquid until the substrates W are lifted out from the second rinse liquid by the third transfer device 53. Since the substrate W exists below the liquid surface of the second rinse liquid, the surface tension of the second rinse liquid does not act on the substrate W, which may prevent the collapse of uneven patterns on the substrate W.

Next, the third transfer device 53 transfers the substrates W of the lot L, which are held in the second rinse liquid by the second transfer arm 52c, to the second delivery table 54. For example, the third transfer device 53 transfers the substrates W one by one to the second delivery table 54. To prevent the collapse of uneven patterns due to the drying of the upper surface of the substrate W on the second delivery table 54, pure water is discharged onto the upper surface of the substrate W, thereby forming a second liquid film LF2 that is a pure water film.

Next, the fourth transfer device 61 receives the substrates W from the second delivery table 54 and transfers the substrates W to the liquid processing device 62.

Next, the liquid processing device 62 processes the substrates W one by one with a liquid (step S5 in FIG. 6). There may be multiple types of liquids such as pure water (e.g., DIW) and a drying liquid having a lower surface tension than pure water. The drying liquid may be an alcohol such as IPA. The liquid processing device 62 supplies pure water and a drying liquid in this order to the upper surface of the substrate W to form a liquid film of the drying liquid.

Next, the fourth transfer device 61 receives the substrate W from the liquid processing device 62, holding the substrate W horizontally with the liquid film of the drying liquid facing upward. The fourth transfer device 61 then transfers the substrate W from the liquid processing device 62 to the drying device 63.

Next, the drying device 63 dries the substrates W one by one with a supercritical fluid (step S5 in FIG. 6). The drying liquid may be replaced with the supercritical fluid, which may prevent the collapse of uneven patterns on the substrate W due to the surface tension of the drying liquid. Since the supercritical fluid requires a pressure-resistant container, processing is performed in a single-substrate mode rather than batch processing to minimize the size of the pressure-resistant container.

The drying device 63 is of a single-substrate type in the present embodiment, but may be of a batch type as described above. A batch-type drying device 63 dries a plurality of substrates W each having a liquid film formed thereon at once with a supercritical fluid. While the single-substrate type drying device 63 has one transfer arm to hold the substrate W, the batch-type drying device 63 has a plurality of transfer arms.

In the present embodiment, the drying device 63 dries the substrate W by supercritical drying, but the drying method is not particularly limited. Any drying method capable of preventing the collapse of uneven patterns on the substrate W may be employed, and may be, for example, spin drying, scan drying, or hydrophobic drying. In spin drying, the liquid processing device 62 rotates the substrate W to remove the drying liquid from the upper surface of the substrate W by shaking the drying liquid off the substrate W with centrifugal force. In scan drying, the supply position of the drying liquid is moved from the center of the substrate W toward the outer periphery of the substrate W while rotating the substrate W to shake the liquid film off the substrate W with centrifugal force. In scan drying, the supply position of a drying gas such as nitrogen gas may also be moved from the center of the substrate W toward the outer periphery of the substrate W in synchronization with the movement of the supply position of the drying liquid.

Next, the fourth transfer device 61 receives the substrate W from the drying device 63 and transfers the substrate W to the first delivery table 33.

Next, the substrate transfer device 31 receives the substrate W from the first delivery table 33 and accommodates the substrate W in the cassette C (step S6 in FIG. 6). The cassette C accommodating a plurality of substrates W is unloaded from the loading/unloading section 2. Through the above steps, the substrate processing method according to the embodiment is completed.

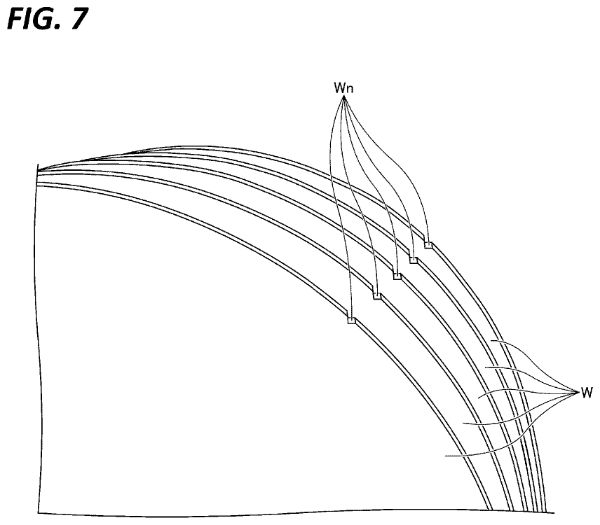

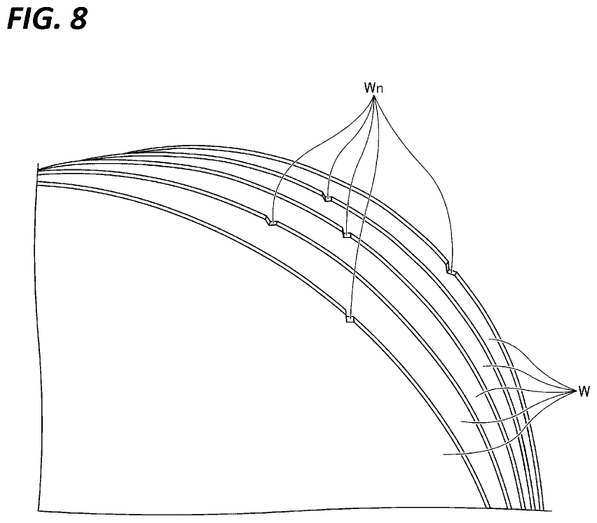

FIG. 7 is a view illustrating an example of a position of the notch Wn before chemical liquid processing. FIG. 8 is a view illustrating an example of a position of the notch Wn after chemical liquid processing. FIGS. 7 and 8 each illustrate five substrates W, which are part of a plurality of substrates W constituting a lot.

As illustrated in FIG. 7, before chemical liquid processing is performed in the chemical liquid tank 41, a plurality of substrates W are held by the processing tool 44 in a state where the positions of the notches Wn are aligned between the substrates W. In contrast, as illustrated in FIG. 8, after chemical liquid processing is performed in the chemical liquid tank 41, each substrate W held by the processing tool 44 may rotate on the processing tool 44, resulting in variations in the positions of the notches Wn between the plurality of substrates W. In particular, when the substrate W subjected to chemical liquid processing is warped (for example, saddle warping), the amount of rotation of the substrate W on the processing tool 44 tends to increase. When the plurality of substrates W with varied positions of the notches Wn are loaded into the single-substrate processing section 6, respectively, each substrate W is processed by the liquid processing device 62 and the drying device 63 while the positions of the notches Wn between the plurality of substrates W are different. In this case, variations in process performance between the plurality of substrates W are more likely to occur. The process performance includes factors such as pattern collapse resistance, liquid splashing differences due to substrate flutter during rotation, particle performance, and etching performance.

Hereinafter, a technique is described that reduces variations in process performance between a plurality of substrates W by identifying the position of the notch Wn of each substrate W after processing in the batch processing section 4 and rotating each substrate W so that the position of the notch Wn reaches a first position.

### [Notch Position Adjustment Control]

An example of control (hereinafter, referred to as “notch position adjustment control”) that adjusts the position of the notch Wn of a plurality of substrates W after processing in the batch processing section 4 will be described.

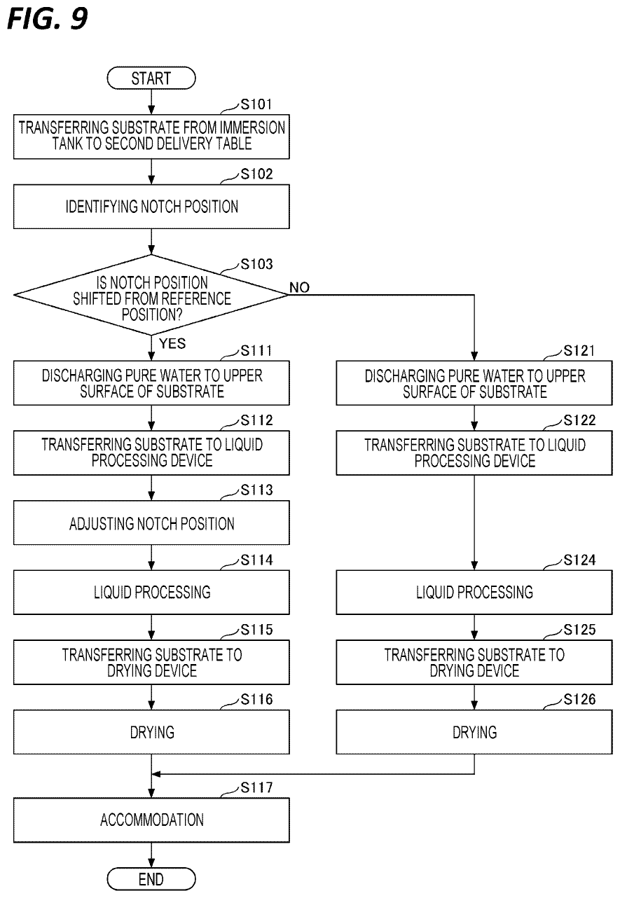

FIG. 9 is a flowchart illustrating an example of notch position adjustment control. The notch position adjustment control illustrated in FIG. 9 is executed under the control of the control circuit 9.

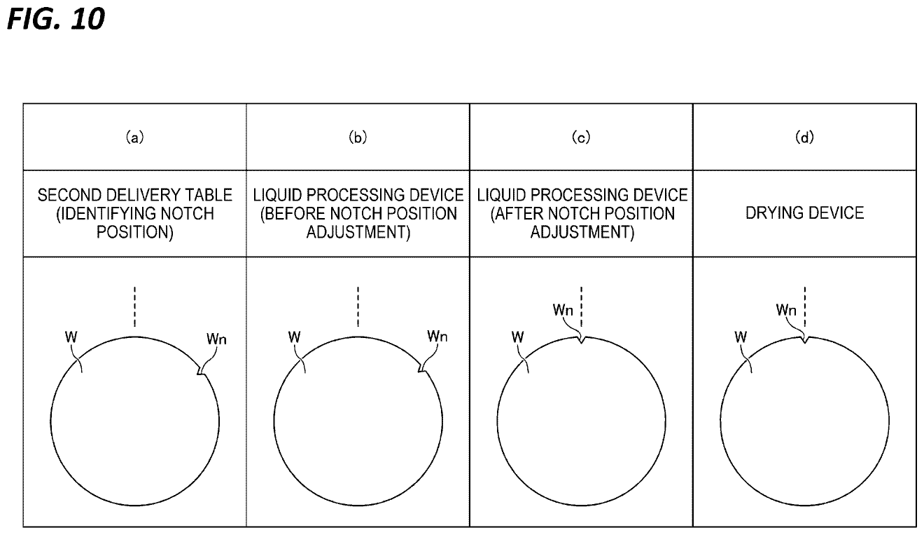

FIG. 10 is a diagram illustrating an example of notch position adjustment control. In FIG. 10, part (a) illustrates the substrate W on the second delivery table 54, part (b) and part (c) illustrate the substrate W in the liquid processing device 62, and part (d) illustrates the substrate W in the drying device 63. Part (b) illustrates the substrate W before the position of the notch Wn is adjusted, and part (c) illustrates the substrate W after the position of the notch Wn has been adjusted. In parts (a) to (d), the reference position is indicated by a broken line. In the example of FIG. 10, the reference position is in the 0 o'clock direction. The reference position on the second delivery table 54 is, for example, the position farthest from the loading/unloading port through which the substrate W is loaded and unloaded by the fourth transfer device 61 (the position on the positive X-axis side in FIG. 1). The reference position in the liquid processing device 62 is, for example, the position farthest from the gate 112 through which the substrate W is loaded and unloaded by the fourth transfer device 61 (the position on the positive Y-axis side in FIGS. 1 and 4). The reference position in the drying device 63 is, for example, the position farthest from the loading/unloading port 132 through which the substrate W is loaded and unloaded by the fourth transfer device 61 (the position on the positive Y-axis side in FIGS. 1 and 5).

In step S101, the third transfer device 53 transfers the substrate W from the immersion tank 51 to the second delivery table 54. In the second delivery table 54, three pins 72 hold the substrate W horizontally. At this time, the first liquid film LF1, which is a liquid film of the second rinse liquid, is formed on the upper surface of the substrate W. The substrate W held by the three pins 72 may have a position of the notch Wn shifted from the reference position. In the example illustrated in FIG. 10, as illustrated in part (a), the reference position is in the 0 o'clock direction and the position of the notch Wn is in the 2 o'clock direction.

In step S102, the imaging unit 75 captures an image of the upper surface of the substrate W held by the three pins 72 to acquire the upper surface image of the substrate W. The imaging unit 75 transmits the acquired upper surface image to the control circuit 9. The control circuit 9 identifies the position of the notch Wn of the substrate W based on the upper surface image acquired by the imaging unit 75. In the example of FIG. 10, the control circuit 9 identifies that the position of the notch Wn is in the 2 o'clock direction.

In step S103, the control circuit 9 determines whether the position of the notch Wn identified in step S102 is shifted from the reference position. In the example of FIG. 10, the control circuit 9 determines that the position of the notch Wn is shifted from the reference position since the position of the notch Wn differs from the reference position.

When the control circuit 9 determines in step S103 that the position of the notch Wn is shifted from the reference position (YES in step S103), the control circuit 9 proceeds to step S111. The control circuit 9 performs steps S111 to S117 described below in this order.

In step S111, the pure water supply unit 80 discharges pure water to the upper surface of the substrate W. As a result, the second liquid film LF2, which is a liquid film of pure water, is formed on the upper surface of the substrate W. After the second liquid film LF2 is formed on the upper surface of the substrate W, the pure water supply unit 80 stops the discharge of pure water to the substrate W.

In step S112, the fourth transfer device 61 transfers the substrate W from the second delivery table 54 to the liquid processing device 62. In the liquid processing device 62, the substrate holding unit 114 holds the substrate W horizontally. The substrate W held by the substrate holding unit 114 retains the position of the notch Wn of the substrate W immediately before being unloaded from the second delivery table 54. Therefore, the position of the notch Wn remains shifted from the reference position. In the example of FIG. 10, as illustrated in part (b), the reference position is in the 0 o'clock direction and the position of the notch Wn is in the 2 o'clock direction.

In step S113, the substrate rotating unit 115 rotates the substrate holding unit 114, thereby rotating the substrate W together with the substrate holding unit 114 so that the position of the notch Wn identified in step S102 becomes the first position. The first position is, for example, the reference position. The first position may also be a different position from the reference position. The first position may be a desired position set in the processing recipe. The desired position is determined, for example, based on the characteristics of the substrate W that underwent drying in the drying device 63 in the past. The characteristics of the substrate W include, for example, the distribution of the collapse of uneven patterns within the plane of the substrate W. In the example of FIG. 10, as illustrated in part (c), the position of the notch Wn is in the 0 o'clock direction and coincides with the reference position.

In step S114, the liquid processing device 62 performs liquid processing for processing the substrate W with a processing liquid. The processing liquid may be, for example, pure water such as DIW, and a drying liquid having a lower surface tension than pure water. The drying liquid may be an alcohol such as IPA. The liquid processing device 62 supplies pure water and a drying liquid in this order to the upper surface of the substrate W to form a liquid film of the drying liquid.

In step S115, the fourth transfer device 61 transfers the substrate W from the liquid processing device 62 to the drying device 63. In the drying device 63, the holding unit 135 holds the substrate W horizontally with the liquid film of the drying liquid facing upward. The substrate W held by the substrate holding unit 135 retains the position of the notch Wn of the substrate W immediately before being unloaded from the liquid processing device 62. Therefore, the position of the notch Wn coincides with the first position. In the example of FIG. 10, as illustrated in part (d), the position of the notch Wn is in the 0 o'clock direction and coincides with the reference position.

In step S116, the drying device 63 performs drying to dry the substrate W with a supercritical fluid. The drying liquid may be replaced with a supercritical fluid, which may prevent the collapse of uneven patterns on the substrate W due to the surface tension of the drying liquid.

In step S117, the fourth transfer device 61 receives the substrate W from the drying device 63 and transfers the substrate W to the first delivery table 33. Next, the substrate transfer device 31 receives the substrate W from the first delivery table 33 and accommodates the substrate W inside the cassette C. The cassette C accommodating a plurality of substrates W is unloaded from the loading/unloading section 2.

When the control circuit 9 determines in step S103 that the position of the notch Wn is not shifted from the reference position (NO in step S103), the control circuit 9 proceeds to step S121. The control circuit 9 performs steps S121, S122, S124, S125, S126, and S117 described below in this order.

Steps S121, S122, S124, S125 and S126 are the same as steps S111, S112, S114, S115 and S116, respectively. That is, when the position of the notch Wn is not shifted from the reference position, the control circuit 9 performs liquid processing and drying without adjusting the position of the notch Wn, and proceeds to step S117.

As described above, according to the embodiment, the position of the notch Wn of the substrate W is identified before drying is performed on the substrate W, and the substrate W is rotated so that the identified position of the notch Wn reaches the first position. In this case, drying may be performed on the substrate W in a state where the positions of the notches Wn are aligned between a plurality of substrates W. Therefore, it is possible to reduce variations in process performance between the plurality of substrates W. Further, since all of the positions of the notches Wn after drying may be aligned between the plurality of substrates W, variations in a process (hereinafter also referred to as “post-process”) performed on the substrate W after being unloaded from the substrate processing system 1 may be improved. Further, it is possible to omit a post-process of aligning the positions of the notches Wn between the plurality of substrates W. This may improve productivity and reduce process performance deterioration due to Q-time.

In the example of FIGS. 9 and 10A to 10D, a case where the imaging unit 75 captures an image of the upper surface of the substrate W before the pure water supply unit 80 discharges pure water to the substrate W has been described, but the present disclosure is not limited thereto. For example, the imaging unit 75 may capture an image of the upper surface of the substrate W after the pure water supply unit 80 supplies pure water to the substrate W. That is, steps S111 and S121 may be performed between steps S101 and S102.

In the example of FIGS. 9 and 10, a case where the imaging unit 75 acquires an image of the upper surface of the substrate W held by three pins 72 on the second delivery table 54 and the control circuit 9 identifies the position of the notch Wn of the substrate W based on the upper surface image has been described, but the present disclosure is not limited thereto. For example, while the third transfer device 53 transfers the substrate W, the imaging unit 53b may acquire an upper surface image of the substrate W being transferred by the third transfer arm 53a, and the control circuit 9 may identify the position of the notch Wn of the substrate W based on the upper surface image. For example, while the fourth transfer device 61 transfers the substrate W, the imaging unit 61c may acquire an upper surface image of the substrate W being transferred by the fourth transfer arm 61b, and the control circuit 9 may identify the position of the notch Wn of the substrate W based on the upper surface image. For example, in the liquid processing device 62, the imaging unit 121 may acquire an upper surface image of the substrate W held by the substrate holding unit 114, and the control circuit 9 may identify the position of the notch Wn of the substrate W based on the upper surface image.

In the example of FIGS. 9 and 10, a case where the substrate rotating unit 15 rotates the substrate holding unit 114 to rotate the substrate W so that the position of the notch Wn reaches the first position in the liquid processing device 62, but the present disclosure is not limited thereto. For example, the substrate W may be rotated on the second delivery table 54 so that the position of the notch Wn reaches the first position.

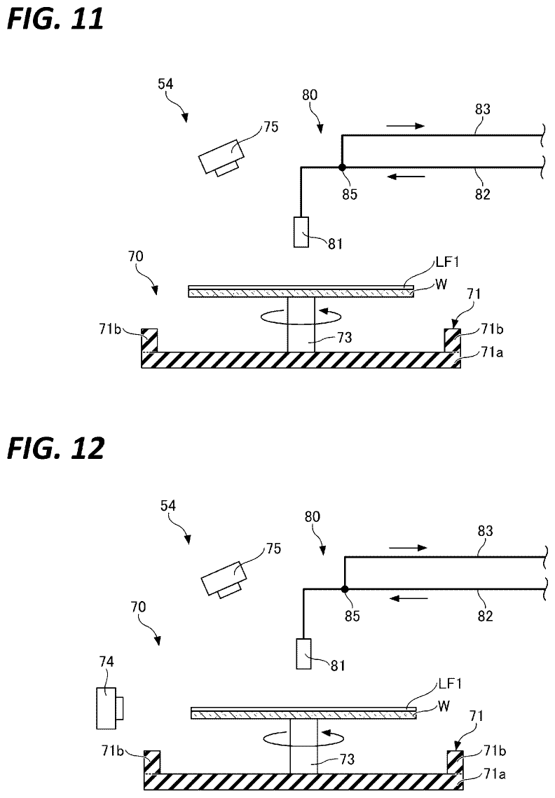

FIG. 11 is a view illustrating a first modification of the second delivery table 54 of FIG. 1. As illustrated in FIG. 11, the substrate holding unit 70 may include a rotary chuck 73 instead of the plurality of pins 72. The rotary chuck 73 holds the substrate W by suction to be rotatable around a vertical axis. The rotary chuck 73 rotates the substrate W so that the position of the notch Wn reaches the first position.

In the example of FIGS. 9 and 10, a case where the desired position in step S113 is determined based on the characteristics of the substrate W that underwent drying in the drying device 63 in the past has been described, but the present disclosure is not limited thereto. For example, the desired position in step S113 may be determined based on the amount of warpage of the substrate W, either in addition to or instead of the characteristics of the substrate W that underwent drying in the drying device 63 in the past.

FIG. 12 is a view illustrating a second modification of the second delivery table 54 of FIG. 1. As illustrated in FIG. 12, the second delivery table 54 may further include an imaging unit 74, and the substrate holding unit 70 may include the rotary chuck 73 instead of the plurality of pins 72.

The imaging unit 74 is provided on the side of the substrate W held by suction on the rotary chuck 73. The imaging unit 74 captures an image of the substrate W, which is rotating around a vertical axis while being held by suction on the rotary chuck 73, from the side, thereby acquiring an end surface image of the substrate W. The imaging unit 74 transmits the acquired end surface image to the control circuit 9. The control circuit 9 calculates the amount of warpage of the substrate W based on the end surface image acquired by the imaging unit 74. The control circuit 9 may determine a desired position based on the calculated amount of warpage. The imaging unit 74 may have the same configuration as the imaging unit 53b. The imaging unit 74 only needs to be capable of capturing an image of the substrate W held by the rotary chuck 72 by suction from the side. In the example of FIG. 12, a single imaging unit 74 is provided, but two or more imaging units 74 may be provided.

Instead of the imaging unit 74, a laser displacement meter may be provided above the substrate holding unit 70. For example, when the third transfer device 53 loads the substrate W onto the second delivery table 54, the laser displacement meter may measure the height of the substrate W at a plurality of positions, including the height at the center position of the substrate W and the height at the peripheral position of the substrate W, and the control circuit 9 may calculate the amount of warpage of the substrate W based on the heights at the plurality of positions. For example, when the fourth transfer device 61 unloads the substrate W from the second delivery table 54, the laser displacement meter may measure the height of the substrate at a plurality of positions, including the height at the center position of the substrate W and the height at the peripheral position of the substrate W, and the control circuit 9 may calculate the amount of warpage of the substrate W based on the heights at the plurality of positions. The laser displacement meter may be one, or two or more.

The above embodiments have described a case where the liquid processing device 62 is located on the positive Y-axis side relative to the fourth transfer device 61, but the present disclosure is not limited thereto. For example, the liquid processing device 62 may be located on the negative Y-axis side relative to the fourth transfer device 61. In this case, the position farthest from the gate through which the substrate W is loaded and unloaded by the fourth transfer device 61 (the position on the negative Y-axis side) is the reference position.

The above embodiments have described a case where the position of the notch Wn of the substrate W is identified based on the upper surface image of the substrate W captured by the imaging unit 75, but the present disclosure is not limited thereto. For example, the position of the notch Wn of the substrate W may be identified by a notch sensor. The notch sensor is provided, for example, on the second delivery table 54. The notch sensor may also be provided in the liquid processing device 62.

The above embodiments have described a case where a cutout is the notch Wn, but the present disclosure is not limited thereto. The cutout may be any portion formed to indicate the crystal orientation of the substrate W. The cutout may be an orientation flat.

According to the present disclosure, it is possible to reduce variations in process performance.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing method comprising:
performing a batch processing to process a plurality of substrates at once;
performing a single-substrate processing to process the plurality of substrates one by one after the batch processing;
identifying a position of a cutout provided on an outer periphery of a substrate subjected to the batch processing; and
rotating the substrate such that the position of the cutout reaches a first position,
wherein the performing the single-substrate processing includes drying the substrate, and
the rotating the substrate is performed before the drying the substrate.

2. The substrate processing method according to claim 1, wherein the first position is determined based on a characteristic of the substrate after the drying the substrate was performed in the past.

3. The substrate processing method according to claim 2, wherein the substrate has an uneven pattern on a surface thereof, and
the characteristic of the substrate includes a distribution of collapse of the uneven pattern in a plane of the substrate.

4. The substrate processing method according to claim 1, wherein the performing the single-substrate processing includes processing the substrate with a processing liquid before the drying the substrate, and
wherein the rotating the substrate is performed before the processing the substrate with the processing liquid.

5. The substrate processing method according to claim 1, wherein the performing the single-substrate processing includes processing the substrate with a processing liquid before the drying the substrate, and
the rotating the substrate is performed after the processing the substrate with the processing liquid.

6. The substrate processing method according to claim 4, wherein the processing the substrate with the processing liquid includes forming a liquid film of a drying liquid on an upper surface of the substrate, and
the drying the substrate includes drying the substrate by replacing the liquid film of the drying liquid with a supercritical fluid.

7. The substrate processing method according to claim 1, further comprising:
holding the substrate in a horizontally after the performing the batch processing and before the performing the single-substrate processing,
wherein the identifying the position of the cutout is performed simultaneously with the holding the substrate horizontally.

8. The substrate processing method according to claim 7, wherein the holding the substrate horizontally includes supplying a processing liquid to an upper surface of the substrate to suppress drying of the upper surface of the substrate, and
the identifying the position of the cutout is performed before the supplying the processing liquid.

9. The substrate processing method according to claim 1, further comprising:
calculating an amount of warpage of the substrate after the performing the batch processing,
wherein the first position is determined based on the amount of warpage of the substrate.

10. The substrate processing method according to claim 1, wherein the cutout is a notch or an orientation flat.

11. A substrate processing system comprising:
a batch processing section configured to process a plurality of substrates at once;
a single-substrate processing section configured to process the substrates one by one;
an identifier including a camera configured to identify a position of a cutout provided on an outer periphery of the substrate;
a rotator including a motor configured to rotate the substrate; and
a control circuit,
wherein the control circuit is configured to:
control the batch processing section to perform a batch processing to process the plurality of substrates at once;
control the single-substrate processing section to perform a single-substrate processing to process the plurality of substrate one by one after the batch processing;
control the identifier to identify the position of the cutout provided on the outer periphery of the substrate subjected to the batch processing; and
control the rotator to rotate the substrate such that the position of the cutout reaches a first position,
wherein the performing the single-substrate processing includes drying the substrate, and
wherein the rotating the substrate is performed before the drying the substrate.
